(19) United States
(12) Patent Application Publication
(10) Pub. No.: US 2013/0164173 A1
(43) Pub. Date: Jun. 27, 2013

(54) PLASMA EMITTER

(71) Applicant: Elwood G. Norris, Poway, CA (US)

(72) Inventor: Elwood G. Norris, Poway, CA (US)

(21) Appl. No.: 13/532,332

(22) Filed: Jun. 25, 2012

Related U.S. Application Data
(60) Provisional application No. 61/500,925, filed on Jun. 24, 2011.

(51) Int. Cl. H01J 37/32

(52) U.S. Cl. CPC H01J 37/32055
USPC 422/29; 313/231.41; 315/111.21; 422/186.04; 29/825

(57) ABSTRACT

An apparatus for producing plasma comprises a first electrode and a porous element. The first electrode is in direct contact with a first side of the porous element. A second electrode is positioned adjacent a second side of the porous element, at least a portion of the second electrode being spaced from the second side of the porous element so as not to be in direct contact with the second side of the porous element. A plasma generating region is defined adjacent the second electrode.

### CROSS-REFERENCE TO RELATED APPLICATIONS AND CLAIM OF PRIORITY

This application claims the benefit of copending U.S. Provisional Patent Application Ser. No. 61/500,925 filed on Jun. 24, 2011, which is hereby incorporated herein by reference in its entirety.

### FIELD OF THE INVENTION

The present invention relates generally to plasma emitters. More particularly, the present invention relates to apparatuses, systems, and methods utilizing plasma emitters over a range of applications including sterilization and decontamination. As such, the present invention relates to the fields of electrical engineering, chemistry, biotechnology, and material science.

### BACKGROUND OF THE INVENTION

Plasma is a collection of charged particles, containing about equal numbers of positive ions and negative ions plus electrons. It is typically an aeroform fluid, similar to a gas. However, unlike most gasses, plasma is a relatively good conductor of electricity and is affected by magnetic fields.

Plasma can be formed in a number of different manners. One method of forming plasma is by creating an electrical potential differential between two electrodes that have a medium between them, such as a gas. As the electrical potential increases between the plates, the positive portions of the gas are drawn toward the negatively charged electrode, and the negative portions of the gas are drawn toward the positively charged electrode. At a certain potential, the valence electrons or other negative components of certain gasses are torn from the rest of the species, creating positive ions, negative ions, and free electrons. These ions and electrons tend to dissociate as described above and recombine repeatedly in the plasma. However, during the times when they exist as charged species, they tend to make the plasma very reactive.

Plasma generation devices are powered by radio frequency current sources, lower frequency alternating current sources, or direct current sources. Electrodes can be fashioned from both metallic and nonmetallic materials. However, direct current sources do not tend to work reliably with nonmetallic electrodes but, rather, tend to initially arc from a somewhat random location, and then tend to preferentially arc from that location thereafter. Thus, the combination of direct current and nonmetallic electrodes typically does not produce a uniform and well defined plasma.

A radio frequency current source can be used with nonmetallic electrodes to form a uniform plasma. However, radio frequency current sources tend to be somewhat inefficient and have other drawbacks in certain applications. For example, radio frequency current sources have a detectable radio frequency signature, which may be undesirable. They also tend to be more expensive than direct current sources.

As such, research and developmental efforts continue in the area of plasma generating apparatuses and associated systems and methods.

### SUMMARY OF THE INVENTION

In accordance with one embodiment, the present disclosure provides an apparatus for producing plasma, comprising: a first electrode; a porous element having the first electrode in direct contact to a first side of the porous element; a second electrode, the second electrode not in direct contact to a second side of the porous element, the second side opposed to the first side; and a plasma generating region adjacent to the second electrode.

Additionally, a method of producing plasma can comprise providing a first electrode; providing a porous element having the first electrode in direct contact to a first side of the porous element; providing a second electrode, the second electrode not in direct contact to a second side of the porous element, the second side opposed to the first side; forming a plasma generation region adjacent to the second electrode; connecting a first conductive connector to the first electrode; connecting a second conductive connector to the second electrode; connecting a power source to the first conductive connector; connecting the power source to the second conductive connector; introducing a gas within the plasma generation region; applying a first electrical potential with the power source to the first conductive connector, thereby applying the first electrical potential to the first electrode; receiving the first electrical potential at the first electrode; conducting the first electrical potential from the first electrode via the porous element to the second electrode; and applying a second electrical potential with the power source to the second conductive connector, thereby applying the second electrical potential to the second electrode and forming a plasma with the gas within the plasma generation region.

Additional features and advantages of the invention will be apparent from the detailed description which follows, taken in conjunction with the accompanying drawings, which together illustrate, by way of example, features of the invention.

### BRIEF DESCRIPTION OF THE DRAWINGS

FIG. 1 is a schematic representation of a plasma emitter in accordance with an embodiment of the present invention;

FIG. 2 is a schematic representation of a plasma emitter in accordance with an embodiment of the present invention;

FIG. 3 is a schematic representation of an appliance in accordance with an embodiment of the present invention; and

FIG. 4 includes a chart showing the effect on bacteria after treatment using the present invention.

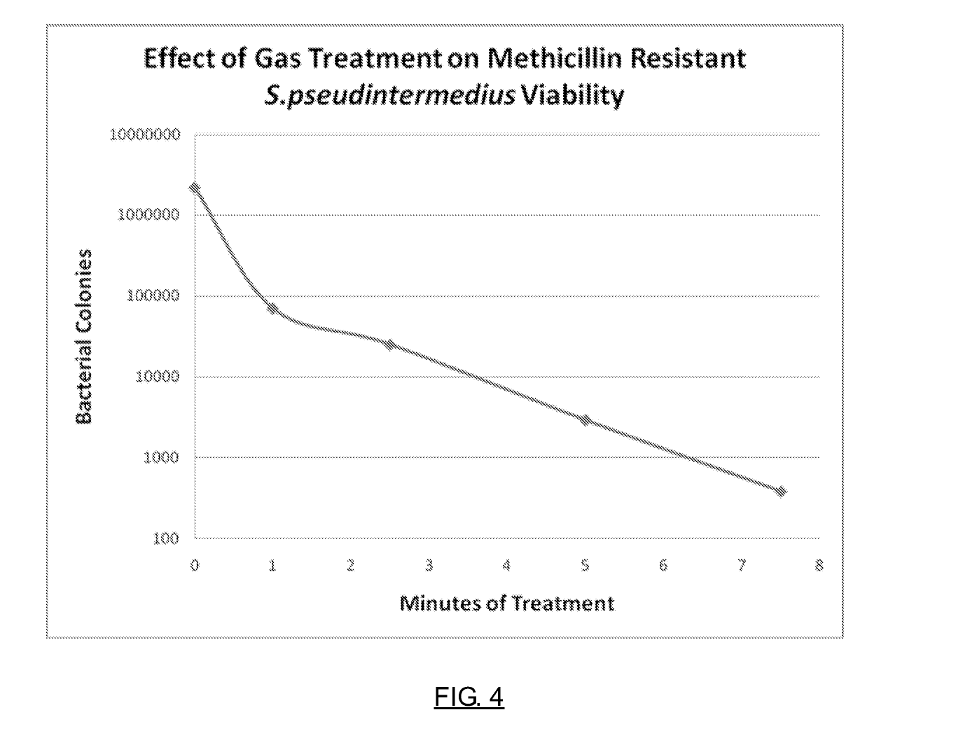

### DETAILED DESCRIPTION

Reference will now be made to the exemplary embodiments illustrated in the drawings, and specific language will be used herein to describe the same. It will nevertheless be understood that no limitation of the scope of the invention is thereby intended. Alterations and further modifications of the inventive features illustrated herein, and additional applications of the principles of the inventions as illustrated herein, which would occur to one skilled in the relevant art and having possession of this disclosure, are to be considered within the scope of the invention.

It is noted that, as used in this specification and the appended claims, the singular forms “a,” “an,” and “the” can include plural referents unless the context clearly dictates otherwise. Thus, for example, reference to “a plasma” can include one or more of such materials, reference to “a ceramic” can include reference to one or more of such ceramics, and reference to “a forming step” can include reference to one or more of such steps.

### Definitions

In describing and claiming the present invention, the following terminology will be used in accordance with the definitions set forth below.

As used herein, “plasma” refers to a state of matter similar to gas in which a certain portion of the particles of a material are ionized such that the plasma contains charged particles, positive ions and negative electrons. Generally, the plasma is electrically conductive so that it responds strongly to electromagnetic fields.

As used herein, “cold plasma” refers to a plasma that is generated at or near room temperature. While the overall temperature of the cold plasma generated can vary, it typically does not exceed about 120 degrees F. In some embodiments, the temperature is low enough so as to not pose a danger of burning a human hand, should such contact occur (although, due to the electrical current flowing in the device, touching the plasma generation region is not advisable).

As used herein, the term “about” is used to provide flexibility to a numerical range endpoint by providing that a given value may be “a little above” or “a little below” the endpoint. The degree of flexibility of this term can be dictated by the particular variable and would be within the knowledge of those skilled in the art to determine based on experience and the associated description herein.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited.

As an illustration, a numerical range of “about 10 to about 50” should be interpreted to include not only the explicitly recited values of about 10 to about 50, but also include individual values and sub-ranges within the indicated range. Thus, included in this numerical range are individual values such as 20, 30.5, and 40 and sub-ranges such as from 10-30, from 20-40, and from 30-50, etc. This same principle applies to ranges reciting only one numerical value. Furthermore, such an interpretation should apply regardless of the breadth of the range or the characteristics being described.

### Invention

The present disclosure provides a plasma emitter that can be used for a variety of applications. The plasma emitters described herein can be integrated with or into various appliances and devices. The plasma emitters can be used for sterilization and/or decontamination. Various applications can include the sterilization of surfaces, e.g., in medical instruments, modifying the chemical composition of gasses, e.g. for decontamination purposes, modifying the surface properties of materials, e.g. application of ink to plastic surfaces, modifying the electrical properties of air to prevent damage by microwave weapons, etc.

It has been recognized that the present plasma emitters can overcome the problems of the prior art by producing an efficient and stable plasma region at atmospheric pressure, low temperatures and at low voltage. Additionally, the present plasma emitters can be used to disinfect (e.g. by sterilization and/or decontamination) by killing contaminates such as bacteria, spores, and/or viruses. Further, it is understood that the present plasma emitters can be varied in size as desired by those skilled in the art based upon the particular application for which it is used.

In accordance with this, it is noted that when discussing the present apparatuses, devices, appliances, and associated methods, each of these discussions can be considered applicable to each of these examples, whether or not they are explicitly discussed in the context of that example. For example, in discussing a porous material for use in an apparatus, such a porous material can also be used in an appliance, device, a method of producing plasma, or a method of disinfecting an object, and vice versa.

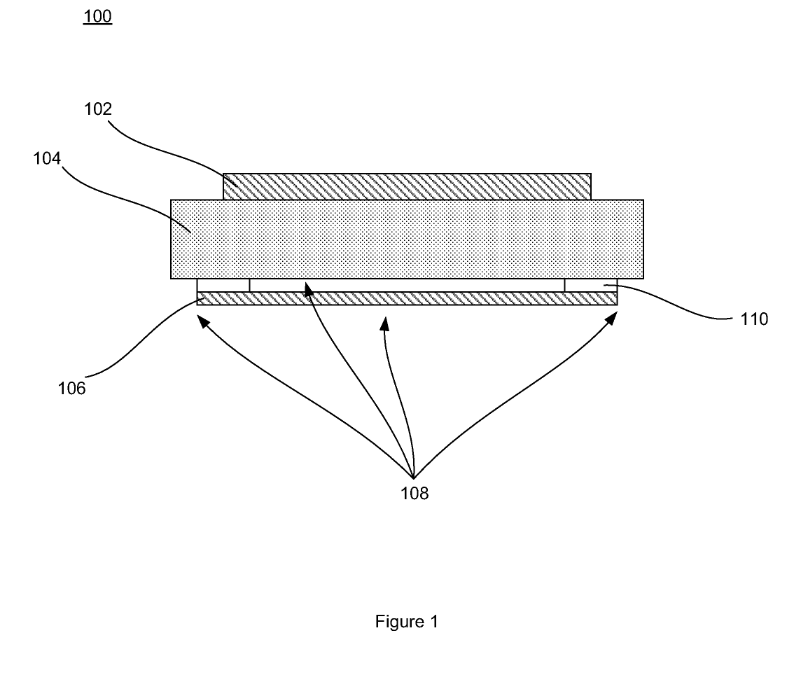

With this in mind, FIG. 1 shows an apparatus 100 for producing plasma, comprising a first electrode 102; a porous element 104 having the first electrode in direct contact to a first side of the porous element; a second electrode 106, at least a portion of which is spaced from, or not in direct contact with, a second side of the porous element (the second side being opposed to the first side). A plasma generating region 108 (sometimes referred to herein as a plasma generation region) can be defined adjacent to the second electrode. Additionally, FIG. 1 shows optional spacers 110 that can be optionally incorporated into various embodiments of the invention. The spacers can serve to maintain separation of the second electrode from the porous element: however, they are not required in every embodiment.

The plasma formed from the present apparatus generally comprises ionized species of gasses present in the plasma generating region when the apparatus is activated. Generally, the system can be used with a variety of gasses to form plasma. The type of gas that can be used to form plasma may be modified to meet the particular needs to which the plasma is applied. In one embodiment, the gas can be air, helium, argon, nitrogen, oxygen, and mixtures thereof. In one aspect, however, the system functions well using only atmospheric air.

Generally, the electrodes described herein can comprise a metal or metal alloy. In one embodiment, the first and/or second electrode can be configured as a solid, a screen, a grate, or a trace. In one aspect, the electrode can be a metal or metal alloy mesh screen. The first and/or second electrode can be smaller than the porous element. In one aspect the first and/or second electrode can be smaller in length and/or width. While not so required, in one aspect, a thickness of the first and/or second electrode(s) is on the order of 1/32 of an inch or less.

Typically, the first and second electrodes will be sized slightly smaller than the porous material such that the edges of the electrodes extend close to the edges of the porous material. Generally, the edges of the electrodes can extend as close to the edges of the porous material as desired, so long as the electrodes do not discharge directly to one another (e.g., the discharge should travel through the porous material, not around the edges of the porous material).

It can be advantageous to form the first and/or second electrodes as meshes, screens or grates for a number of reasons. For example, the mesh or screen configuration assures a broad distribution of discharge, such that “point” charging, or arcing, does not occur. In essence, the grate or mesh or screen provides numerous edges from which discharges can originate. Also, when a mesh or screen is used, the plasma generated adjacent the electrodes can more easily escape the plasma generation zone.

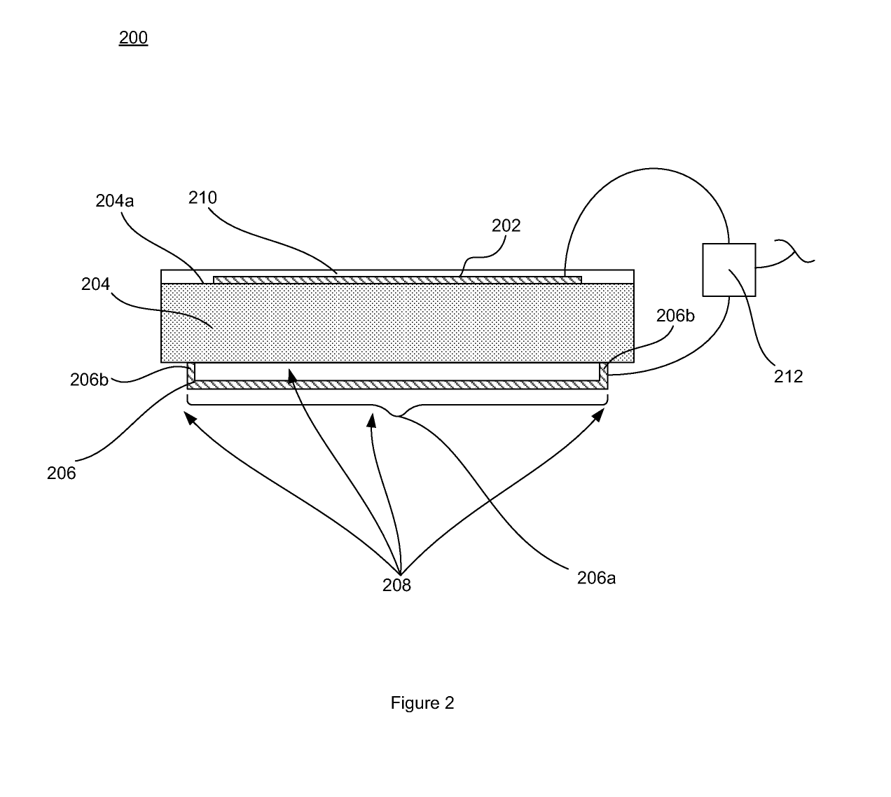

Turing now to FIG. 2, in one aspect of the invention, the first electrode 202 can be in direct contact with the porous element 204 along one side 204a of the porous element. In one embodiment, the first electrode can be placed against one side of the porous element and then encased in an inert material 210 against the porous element. As such, the first electrode can be at least partially encased in an inert material. In one aspect, the electrode is completely encased between the inert material and the porous material. As such, the first electrode can be sealed against the porous element. Such sealing can provide for an air tight and/or water tight sealing of the first electrode. In one embodiment, the inert material can be a polymeric material or resin. In one aspect, the inert material can be an epoxy, such as Professional Heavy Duty 5-Minute Epoxy sold by the Loctite™ company.

Generally, the porous element 204 is oriented between the first electrode and the second electrode 206. In one example, the porous element can include clay, ceramic, sandstone, terra cotta, sintered glass, combinations thereof, or mixtures thereof. In one aspect, the porous element can include ceramic. Additionally, the porous element can be unglazed (e.g., can be devoid of any sealing material applied to the surface thereof). The ceramic can comprise ceramic material including, without limitation, alumina, beryllia, ceria, zirconia, carbide, boride, nitride, silicide, and mixtures thereof. Typically, the plasma emitter is free of any liquid. As such, the plasma emitters described herein can be dry emitters. The porous material can be of any shape, e.g., rectangular, square, round, oval, etc. Additionally, the porous material can be of any dimension commensurate with the application (e.g. decontamination and/or sterilization) as well as the desired plasma generating region.

Notably, one problem that has been encountered when using nonmetallic electrodes is that, before the plasma ignites, the current can be discharged at a point location on the surface of the nonmetallic electrode. This condition is called “arcing.” After the electrode arcs, current tends to preferentially discharge from that point on the nonmetallic electrode during all subsequent attempts to ignite the plasma. Thus, the nonmetallic electrode is rendered substantially inoperable by the arcing. As such, the present disclosure generally provides for a porous material allowing the dissipation of the electric charge across the porous material.

Additionally, in one aspect, the porous material can include a relatively uniform distribution of pores within the porous material thereby further reducing the occurrence of arcing exhibited by a nonmetallic first electrode having a smaller number, or lower distribution of pores. Further, as discussed herein, a relatively greater number of pores within the porous material can reduce the occurrence of arcing as compared to a nonmetallic first electrode having a relatively fewer number of pores within it. However, the number of pores, as defined by the relative amount of total volume of the pores to the total volume of the nonmetallic electrode also can have an upper limit, the upper limit being a pore density that causes arcing on the surface of the porous element. Moreover, arcing may occur if the pore size is too large compared to the size of the porous material, or if the pores are only concentrated within relatively small areas within the porous material, rather than being more uniformly distributed. Either of these conditions may also produce a point on the surface of the porous material where currently preferentially flows, and thus from which arcing may occur.

Generally, as discussed herein, the plasma generating region 208 can be of a size and volume to produce enough plasma to effectuate the purposes of the application. For example, for sterilization and/or decontamination, the plasma generating region can be sufficient to produce enough plasma to kill spores, viruses, and bacteria in a desired volume, e.g., about 0.5 ft³ to 5 ft³. In one embodiment, the porous element can have sides ranging from about 2 inches to about 6 inches with a thickness from about ¼ of an inch to about 1 inch. While plasma emitters of a variety of sizes can be utilized to treat particular areas, multiple emitters can also be utilized (in a parallel relationship) to increase the effective emitter face size. So long as the thickness of the porous material is not increased, increasing the facial area of the porous element does not require a higher voltage be used, but the resultant plasma emitter will require more current.

At least a portion of the second electrode can be spaced from the porous element; thereby generally forming a plasma generating region. In one embodiment, the second electrode can be spaced from about 1/16 of an inch to about 1 inch from the porous element. In another embodiment, the second electrode can be spaced about ¼ of an inch from the porous element. Generally, the spacing can be sufficient to form a stable plasma generating region forming sufficient plasma to effectuate decontamination and/or sterilization of objects within a specified distance from the region as discussed herein. In one embodiment, the plasma generating region can be sufficient to kill bacteria, viruses, and spores.

The plasma generating region generally forms between the second electrode and the porous element, although plasma may form adjacent to the second electrode. For example, the plasma may form in, near, or adjacent to the mesh of a mesh screen electrode. The plasma generating region can form a volume of at least 5 in³. In one embodiment, the plasma generating region can form a volume of about 5 in³ to about 100 in³. The volume of the plasma generating region may be increased or decreased by varying the distance between the porous material and the portion of the second electrode that is spaced apart from the surface of the porous material as well as by varying the size of the plasma emitter and the power supplied to the emitter. As shown in FIG. 1, the second electrode can be spaced apart from the second electrode via spacers 112 such that the spacer is between the second electrode and the porous element. Generally, such spacers can comprise any non-conducting material. In one embodiment, the non-conducting material can be a polymeric material or resin. In one aspect, the non-conducting material can be comprise an acrylate or methacrylate polymer; e.g., poly(methyl methacrylate) (PMMA).

Additionally, as shown in FIG. 2, the second electrode can be configured such that at least a portion 206a of the second electrode is not in direct contact with the porous element. This spacing can be achieved in a number of manners. For example, in one aspect, at least two corners 206b of the second electrode can be bent or otherwise configured to contact the porous material thereby allowing a majority portion 206a of the second electrode to be spaced apart from the porous material. As shown in FIG. 2, in one embodiment, the portion 206a that is spaced apart can constitute a substantial portion of the electrode, i.e., about 80% or more. In one aspect, the portion can constitute a majority of the second electrode (more than 50%). Additionally, in one embodiment, all four corners of the second electrode can be configured to contact the porous element thereby allowing a portion of the second electrode to be spaced apart from the porous material.

The present invention allows for optimal spacing of the second electrode from the porous material in a very simple manner. In one embodiment, the optimal spacing can be empirically determined by altering the spacing (or the voltage) until a vibrant purple-colored discharge is detected visually.

Generally, the electrodes are connected to a power source. The power source can supply AC or DC current. Additionally, as shown in FIG. 2, the apparatuses described herein can contain a step-up transformer 212 depending upon the voltage needed. In one embodiment, the plasma emitters can be operated at a voltage of about 8,000 to about 15,000 volts. In some embodiments, the plasma emitters can be operated at a current of about 10 to about 15 milliamps.

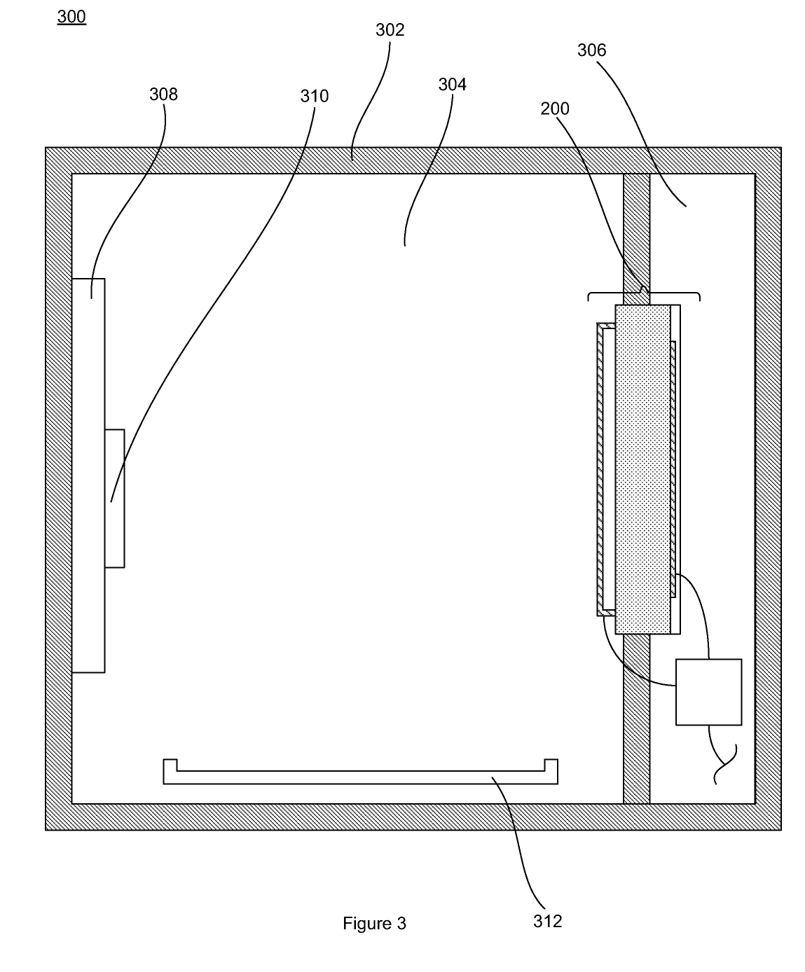

As discussed herein, the present plasma emitters can be used in various appliances and devices. Turning now to FIG. 3, in one embodiment, an appliance 300 can include a plasma emitter apparatus 200 incorporated into an appliance casing 302. The appliance casing can be divided to provide a plasma treating area 304 and an equipment housing area 306. The equipment housing area can contain the plasma emitter apparatus 200 and other associated electrical components such as a display module (not shown), associated wiring (not shown), and power cords (not shown). The appliance can further comprise a carbon filter 308. The carbon filter can be used for the absorption of off gasses associated with the operation of the plasma emitter. In one aspect, the off-gasses can include ozone.

The appliance can be used for decontamination and/or sterilization of objects. Without being bound by any particular theory, it is believed that, in one application, the combination of ozone and plasma can provide a synergistic killing effect for viruses, spores, and bacteria. The use of carbon filters or other organic filters can eliminate the need for a complex venting system that vents off-gasses to a remote region, as has been required with some conventional systems. Additionally, the general use of the present plasma emitters can eliminate the need for high temperatures to effectuate the decontamination and/or sterilization. As such, the present appliance can be run at room temperature, including a range of 20° to 25° C., although the appliance can be operated outside this temperature. As previously discussed, the appliance can be run at atmospheric pressure, although other pressures can also be suitable. The appliance can further comprise a fan 310 connected to the carbon filter such that the gasses in the appliance can be cycled through the carbon filter prior to opening the appliance. Additionally, the appliance can comprise a tray 312 for receiving and/or holding a device to be decontaminated (similar to a conventional microwave oven, the tray can be rotatable within the appliance casing 302, i.e., cabin of the appliance).

While the appliance described herein can function solely as a plasma emitter, in one embodiment, the appliance can function as a microwave in addition to a plasma emitter. As such, it is contemplated herein to modify an existing microwave appliance with a plasma emitter. Such an appliance can provide for microwave emissions as well as plasma generation. Further, such operability may be independent from each other or may be performed simultaneously. For example, the appliance can be first used to decontaminate or sterilize a food product (utilizing the plasma generating system), then can be operated as a standard microwave oven to cook the food product.

The equipment housing area 306 can include various elements that function to provide pre-programmed routines that can be selected to safely decontaminate a product. For example, a locking system (not shown in detail) can be provided that prevents an operator from opening the appliance door until it is safe to do. Readily obtained controlling circuitry can be utilized to provide a decontamination cycle such as the following:

A user can be prompted to begin a decontamination cycle once an object is placed within the device;

A time (or exposure/kill level) can be selected by user and the user can activate the appliance;

Upon initiation, the appliance can automatically lock the door to prevent inadvertent opening of the door during operation;

The plasma generating system can be activated and continue until some predetermined event has been reached (e.g., until a certain time has passed, until a certain level of decontamination has been reached, etc.);

Once the plasma generating system has been deactivated, a purge cycle can be initiated which forces the gasses produced during the cycle through a filtering system (e.g., a carbon filter) for a predetermined amount of time or until a predetermined level of air quality is reached within the cabin of the appliance; and

Once the air quality or other environmental conditions within the cabin are reached, the door can unlock, allowing an operator to open the appliance and remove the decontaminated device.

Generally, a method of producing plasma can comprise providing a first electrode; providing a porous element having the first electrode in direct contact to a first side of the porous element; providing a second electrode, the second electrode not in direct contact to a second side of the porous element, the second side opposed to the first side; forming a plasma generation region adjacent to the second electrode; connecting a first conductive connector to the first electrode; connecting a second conductive connector to the second electrode; connecting a power source to the first conductive connector; connecting the power source to the second conductive connector; introducing a gas within the plasma generation region; applying a first electrical potential with the power source to the first conductive connector, thereby applying the first electrical potential to the first electrode; receiving the first electrical potential at the first electrode; conducting the first electrical potential from the first electrode via the porous element to the second electrode; and applying a second electrical potential with the power source to the second conductive connector, thereby applying the second electrical potential to the second electrode and forming a plasma with the gas within the plasma generation region.

While the present steps have been presented in a linear order for the purposes of description, it is understood that such steps are not necessarily performed in such an order unless otherwise indicated. For example, the step of connecting a power source to the first conductive connector can be performed before, after, or simultaneously with the step of connecting the power source to the second conductive connector.

In one embodiment, the method can further comprise purging off-gasses. In one aspect, the purging can include recycling the off-gasses through an organic filter, e.g., a carbon filter. In another aspect, the purging can include venting the off-gasses.

Additionally, a method of disinfecting an object can comprise placing the object in any of the appliances described herein and supplying current to the first electrode and the second electrode. In one aspect, the object can be in contact with the plasma generating region. In another aspect, the object can be adjacent to the plasma generating region. In one embodiment, the object can be in contact with plasma generated from the plasma generated region. Generally, the object can be in contact with the plasma for a time sufficient to disinfect the object. In one aspect, the object is in contact with the plasma for at least about sixty seconds to about ten minutes. In one embodiment, disinfecting can include sterilization of the object. Sterilization can include substantially killing viruses, spores, and bacteria on a surface of the object. In one aspect, substantially killing can include killing at least 99% of viruses, spores, and bacteria. In another aspect, substantially killing can include killing at least 99.9% of viruses, spores, and bacteria. In still another aspect, substantially killing can include killing at least 99.99% of viruses, spores, and bacteria. Generally, sterilization can include substantially killing viruses, spores, and bacteria on any exposed surface of the object. Additionally, in one aspect, sterilization can include substantially killing viruses, spores, and bacteria on any exposed surface of the object as well as any internal surface of the object. As such, in one embodiment, after the object is removed, the object does not have viable bacteria, viable viruses, or viable spores on any external or internal surface of the object.

In addition to the above, the present plasma emitter apparatuses and appliances can be used for food purification and/or air purification. As such, in one embodiment, the present apparatuses and appliances can be configured to statically or dynamically receive food or air to be purified. For example, for a static mode of operation, the food can be placed in proximity to a plasma emitter or inside an appliance containing such an emitter for treatment. Additionally, in one example, for a dynamic mode of operation, air can be blown across a plasma emitter or cycled through an appliance containing such an emitter for treatment.

Generally, the objects for disinfecting can be any object of interest. In one embodiment, the object can be a medical and/or dental instrument. In one aspect, the medical instrument can be tubing, syringes, scalpels, scissors, forceps, thermometers, needles, saws, stethoscopes, drills, etc. In another aspect, the dental instrument can be tubing, syringes, scalpels, dental picks, needles, drills, mail items, hands and other portions of the body, etc. In another embodiment, the object can be a fabric or article of clothing. In still another embodiment, the object can be a personal object such as a cell phone, pager, wallet, keys, purse, writing instrument, personal digital assistant (“PDA”), electronic device, personal computing device such as laptops, tablets, gaming devices, etc.

It is to be understood that the above-referenced arrangements are only illustrative of the application for the principles of the present invention. Numerous modifications and alternative arrangements can be devised without departing from the spirit and scope of the present invention. While the present invention has been shown in the drawings and fully described above with particularity and detail in connection with what is presently deemed to be the most practical and preferred embodiment(s) of the invention, it will be apparent to those of ordinary skill in the art that numerous modifications can be made without departing from the principles and concepts of the invention as set forth herein.

What is claimed is:

1. An apparatus for producing plasma, comprising:
a first electrode;
a porous element, the first electrode being in direct contact with a first side of the porous element;
a second electrode, positioned adjacent a second side of the porous element, at least a portion of the second electrode being spaced from the second side of the porous element so as not to be in direct contact with the second side of the porous element; and
a plasma generating region defined adjacent the second electrode.

2. The apparatus of claim 1, wherein the first electrode comprises a metal or metal alloy.

3. The apparatus of claim 1, wherein the first electrode is configured as a solid, a screen, or a trace.

4. The apparatus of claim 1, wherein the first electrode is smaller in both length and width than the porous element.

5. The apparatus of claim 1, wherein the porous element is an unglazed ceramic or unglazed clay material.

6. The apparatus of claim 1, wherein the second electrode comprises a metal or a metal alloy.

7. The apparatus of claim 1, wherein the second electrode is configured as a solid or a screen.

8. The apparatus of claim 1, wherein the second electrode is smaller in both length and width than the porous element.

9. The apparatus of claim 1, wherein power source supplies AC or DC current.

10. The apparatus of claim 1, wherein the plasma generating region forms a volume of at least 5 in³.

11. The apparatus of claim 1, wherein the plasma generating region defines a volume of about 5 in³ to about 100 in³.

12. The apparatus of claim 1, wherein the first electrode is at least partially encased in an inert material.

13. The apparatus of claim 12, wherein the inert material is a polymeric material.

14. The apparatus of claim 12, wherein the inert material is an epoxy.

15. The apparatus of claim 1, further comprising a spacer disposed between the second electrode and the porous element.

16. The apparatus of claim 15, wherein the spacer is an electrically non-conducting material.

17. The apparatus of claim 1, further comprising a power source connected to the first electrode and the second electrode.

18. An appliance, comprising the apparatus of claim 1.

19. The appliance of claim 18, wherein a treatment space of the appliance is sufficiently large to treat a human body.

20. The appliance of claim 18, further comprising a carbon filter for absorption of off-gasses.

21. The appliance of claim 20, wherein the off-gasses include ozone.

22. A method of configuring an apparatus for producing plasma, comprising:
obtaining a first electrode;
obtaining a porous element and positioning the first electrode in direct contact with a first side of the porous element;
obtaining a second electrode and positioning the second electrode adjacent, but spaced from, a second side of the porous element, the second side of the porous element being opposed to the first side of the porous element;
defining a plasma generation region adjacent the second electrode;
connecting a first electrically conductive connector to the first electrode;
connecting a second electrically conductive connector to the second electrode;
connecting a power source to the first conductive connector; and
connecting the power source to the second conductive connector.

23. A method of producing plasma using the apparatus of claim 22, comprising:
introducing a gas within the plasma generation region;
applying a first electrical potential with the power source to the first conductive connector, thereby applying the first electrical potential to the first electrode;
conducting the first electrical potential from the first electrode via the porous element to the second electrode; and
applying a second electrical potential with the power source to the second conductive connector, thereby applying the second electrical potential to the second electrode and forming a plasma with the gas within the plasma generation region.

24. The method of claim 23, further comprising purging off-gasses produced during the plasma generation process.

25. The method of claim 24, wherein the off-gasses include ozone.

26. The method of claim 23, wherein the plasma is generated as a cold plasma.

27. A method of disinfecting an object, comprising placing the object in the appliance of claim 19 and supplying current through the first electrode and the second electrode.

28. The method of claim 27, wherein the object is in contact with, or disposed within, the plasma generation region.

29. The method of claim 27, wherein the object is in contact with the plasma generation region for at least about 5 sec.

30. The method of claim 27, wherein the object is selected from the group consisting of a medical instrument, a dental instrument, an article of clothing, a fabric, an electronic device, a personal item, and combinations thereof.

31. The method of claim 27, wherein, after the object is treated within the appliance, at least one surface of the object is devoid of viable bacteria, viable viruses, or viable spores.
